(19) United States
(12) Patent Application Publication
(10) Pub. No.: US 2017/0069772 A1
(43) Pub. Date: Mar. 9, 2017

(54) PHOTOVOLTAIC CELL STRUCTURE AND METHOD OF MANUFACTURING A PHOTOVOLTAIC CELL

(71) Applicant: INSTYTUT FIZYKI PAN, Warszawa (PL)

(72) Inventors: Sylwia GIERALTOWSKA, Warszawa (PL); Marek GODLEWSKI, Warszawa (PL); Grzegorz LUKA, Rzeszow (PL); Rafal PIETRUSZKA, Wilczyce (PL); Lukasz WACHNICKI, Warszawa (PL); Bartlomiej WITKOWSKI, Warszawa (PL)

(21) Appl. No.: 15/121,810

(22) PCT Filed: Feb. 26, 2015
(86) PCT No.: PCT/IB2015/051425

§ 371 Date: Aug. 26, 2016

(30) Foreign Application Priority Data
Feb. 27, 2014 (PL) PL407336

(51) Int. Cl. H01L 31/0224; H01L 31/02; H01L 31/18; H01L 31/074; H01L 31/0236

(52) U.S. Cl. CPC H01L 31/022483; H01L 31/074; H01L 31/02363; H01L 31/1884; H01L 31/02008; H01L 31/022425

(57) ABSTRACT

The invention relates to the photo-voltalic cell structure comprising semiconductor type-p substrate with bottom electric contact upon which the active ZnO film is present, with the transparent conductive layer upon it, preferably ZnO:Al film, with an electric contact, characterized in that the active ZnO layer consists of ZnO nanostructures film at least 50 nm thick, deposited on nucleating layer and covered with ZnO film at least 1 nm thick, and the method to produce the photovoltaic structure.

This invention relates to a photovoltaic cell structure and method to produce the same. Such structures can be used as electric power sources since they generate voltage when subjected to light.

There are descriptions of various kinds of photovoltaic structures in scientific and patent literature. The best known ones comprise silicon PV photovoltaic cells, which constitute almost 90% of the photovoltaic market. Currently, PV panels are commercially available, containing crystalline, thin-film silicon cells. Although significant progress in PV cells/structures based both on monocrystalline and polycrystalline silicon has been observed, the manufacturing technology is still too expensive and in the majority of cases it is simply uneconomical. The remaining 10% of the photovoltaic market consists of photovoltaic cells based on thin-film materials like: cadmium telluride (CdTe), cadmium sulfide (CdS), Copper indium gallium selenide (CIGS) alloys and multijunction cells using A^{III}B^{IV} materials. The drawback of thin-layer CdTe-CdS cells is their high price (especially the cost of tellurium of which there is also too little to satisfy the photovoltaic market needs) as well as their negative environmental impact due to the application of cadmium. Another aspect limiting the applicability of CdTe based technology are the problems connected with the performance of ohmic contacts both for CdTe of p-type and CdS n-type. This impediments make CdTe and CdS difficult materials for photovoltaics. In case of cells based on Copper indium gallium selenide (CIGS) alloy the problem is similar since it is CdS that is used the most often as the partner for p-type conductivity of CIGS. Cells containing multiple layers of various materials are also known, the so-called multijunction cells, produced by means of molecular beam epitaxy (MBE). Structures of such cells are generally built of three layers. The lower layer is the substrate layer of germanium (Ge), the middle layer is an InGaAs multilayer, and the upper layer is also a multilayer, InGaP. The efficiency of the triple-junction cells is in fact the highest (of the magnitude of 40% in laboratory conditions), but their manufacturing cost is very high which makes their mass production impossible. Furthermore, the method to obtain tunnel layers stable in time is very complex, and those high efficiencies are obtained only in focused light conditions under which excessive heating of those cells occurs. From publication by R. Pietruszka, G. Luka, B. S. Witkowski, K. Kopalko, E. Zielony, P. Bieganski, E. Placzek-Popko, M. Godlewski, “Electrical and photovoltaic properties of ZnO/Si heterostructures with ZnO films grown by atomic layer deposition”, Thin Solid Films, doi: 10.1016/j.tsf.2013.10.110, a photovoltaic cell structure is known, produced by means of atomic layer deposition—ALD—technology. The structure is a triple-layer structure in the arrangement of: p-type semiconductor/n-type semiconductor/transparent electrode. The substrate in this structure is the p-type semiconductor being the first layer, the second layer is zinc oxide film (n-type), and the third layer is zinc oxide film with admixture of aluminum. The manufacturing cost of the structure is relatively low in comparison with the commercially manufactured structures, and the efficiency of the cell built of such structures reaches 6%.

The object of the invention is to develop a photovoltaic structure of increased efficiency and relatively cheap production method of such structure.

The first object of the invention is a photovoltaic structure comprising a p-type semiconductor substrate with bottom electric contact upon which the active ZnO film is present with the transparent conductive layer upon it, preferably ZnO:Al film with electric contact. In this structure, the active ZnO layer is placed between the substrate, preferably silicon, and the transparent conducting film layer, preferably ZnO:Al film. It is ZnO nanostructures layer at least 50 nm high, covered with ZnO film at least 1 nm thick. ZnO nanostructures are deposited on the nucleating layer, preferably gold, silver layer or on ZnO layer or on nanoparticles of those materials. Equally preferably, the transparent conducting layer is made of ITO (Indium tin oxide) or SnO₂. ZnO nanostructures can have the form of nanorods.

The second object of the invention is the method of obtaining photovoltaic structure, characterized in that an active ZnO layer in the form of nanorods covered with ZnO film is made on a substrate, preferably silicon, with prepared bottom electric contact. In order to produce the active layer, the substrate is first covered with the nucleating layer. The nucleating layer can be a layer of gold, silver or nanoparticles of those metals deposited by means of cathode sputtering, or a ZnO layer or ZnO nanoparticles deposited from solution or obtained by zinc salt annealing (e.g. zinc acetate) deposited from solution or during at least 1 ALD cycle, where, as zinc precursor, diethylzinc, dimethylzinc or zinc chloride is used, and water, ozone or oxygen plasma as oxygen precursor. Upon depositing the nucleating layer, the substrate is placed in reaction mixture with pH of 6.5-12, containing a solvent, at least one oxygen precursor, and at least one zinc precursor, heated up to the temperature of 30-95° C. and kept in this temperature for at least 1 second. It is preferred when the oxygen precursor in the reaction mixture is water, and the zinc precursor is zinc acetate. Upon completion of the process, impurities are removed from the substrate and crystallized ZnO nanorods, preferably by annealing for at least 1 second in the temperature of ≧100° C., after which ZnO nanorods are covered with ZnO film in ALD process. Preferably, ZnO film is deposited in at least 10 ALD cycles with diethylzinc, dimethylzinc or zinc chloride as zinc precursor, and water, ozone or oxygen plasma as oxygen precursor. Further on, the active layer is covered with a transparent ZnO:Al electrode film, which the upper electric contact is made on. Preferably, the transparent ZnO electrode film with aluminum admixture is deposited in at least 100 ALD cycles with diethylzinc, dimethylzinc or zinc chloride as zinc precursor, and water, ozone or oxygen plasma as oxygen precursor, and trimethylaluminum as aluminum precursor.

The obtained structure generates electrical voltage when subjected to visible, infrared or near UV light spectrum. The technology of execution of photovoltaic structure according to this invention is cheap and simple, and the structure is a multiple use structure.

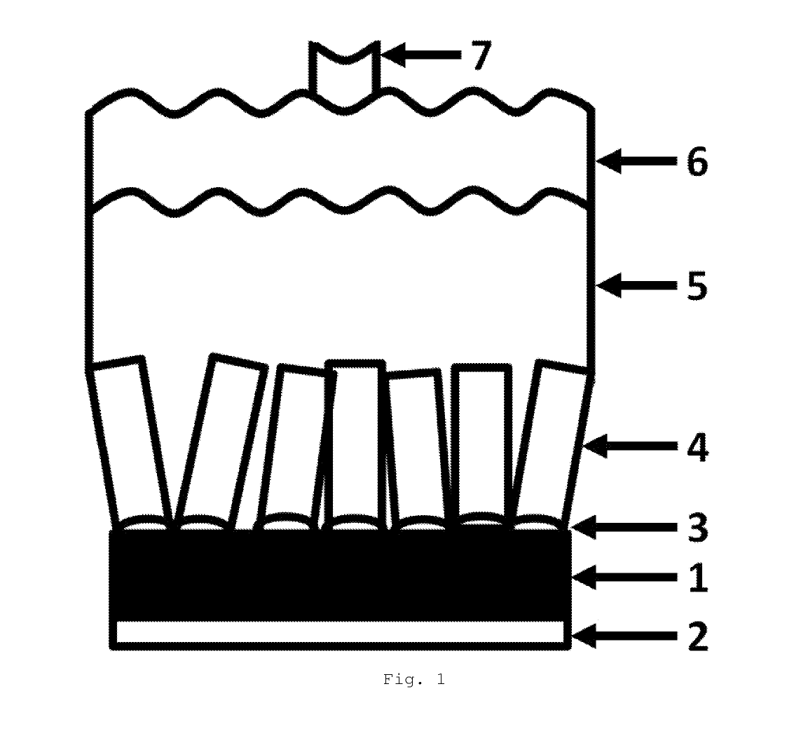

The invention will be explained in more detail with the Al/ZnO/ZnO_{NR}/Si/Al photovoltaic structure embodiment illustrated in FIG. 1.

To carry out the example structure, commercially available p-type silicon substrate with electrical resistivity of 2.3 Ωcm and dimensions of 1.5×1.5 cm was used. First, the substrate was subjected to cleaning carried out in an ultrasonic cleaner. The substrate was cleaned in 3 steps of 30 seconds each, in isopropanol, acetone and deionized water consecutively. Upon the cleaned substrate 1, from the bottom, a film of aluminum 2, constituting the electric contact, was deposited with cathode sputtering. In the second step, the creation of the active ZnO layer in the form of ZnO nanorods 4 covered with thin film of ZnO 5 was commenced. For that purpose, first, silver nanoparticles constituting the nuclei 3 for hydrothermal growth of nanorods were deposited upon the upper surface of the substrate 1 also by cathode sputtering. Then, the substrate with the nuclei was placed in the reaction mixture containing dissolved zinc acetate brought to the pH value of 8. The mixture and the substrate were heated up to the temperature of 50° C. and the growth of nanorods to the height of 650 nm was continued in the temperature for 2 minutes. After the growth completed, the substrate 1 with the crystallized nanorods 4 was rinsed in isopropanol to remove possible impurities, and deposition of ZnO layer 5 upon them started. For that purpose, the substrate was placed in an ALD reactor where it was annealed for 2 minutes in 200° C. After annealing, the reactor chamber was cooled down to 160° C., in which temperature the ZnO nanorods (and the substrate in part) were thoroughly covered with ZnO film ca. 200 nm thick in 1000 ALD cycles. Next, without removing the substrate with the deposited active layer from the ALD reactor, the transparent electrode 6 film was deposited. At the same temperature (160°) in 1700 ALD cycles, the active layer (nanorods 4 covered with ZnO layer 5) was covered with ZnO:Al film 300 nm thick, constituting the upper, transparent electrode 6. The electrode layer 6 was deposited using diethylzinc as zinc precursor, water as oxygen precursor, and trimethylaluminum as aluminum precursor. After depositing the electrode layer 6, the point ohmic contact to the ZnO:Al layer 7 made of aluminum was deposited by cathode sputtering process.

Covering the ZnO nanorods with the additional ZnO layer increased the area of the contact separating the carriers, which significantly increased the efficiency of the structure according to the invention. The obtained structure demonstrated the efficiency of ˜12.5% (laboratory measurements made with sunlight simulator)

1. A photovoltaic cell structure, comprising semiconductor type-p substrate with bottom electric contact upon which the active ZnO film is present, with the transparent conductive layer upon it, preferably ZnO:Al film, with an electric contact, characterized in that the active ZnO layer consists of ZnO nanostructures film at least 50 nm thick, deposited on nucleating layer and covered with ZnO film at least 1 nm thick.

2. The structure according to claim 1, characterized in that the nucleating layer is a layer of gold, silver or ZnO, or nanoparticles of these materials.

3. The method of carrying out the photovoltaic cell structure, wherein upon p-type substrate with bottom electric contact an active layer of ZnO is deposited, upon which a transparent ZnO:Al electrode film and electric contact are deposited, characterized in that upon the substrate, preferably silicon, an active ZnO layer is created in the form of nanorods covered with ZnO film, wherein in order to produce that layer, the substrate is first covered with the nucleating layer, then the substrate with the nucleating layer is placed in a reaction mixture with pH of 6.5-12, containing a solvent, at least one oxygen precursor, and at least one zinc precursor, heated up to the temperature of 30-95° C. and kept in this temperature for at least 1 second, and after completion of this process, impurities are removed from the substrate and crystallized nanorods, preferably by annealing for at least 1 second in the temperature of 100° C., after which the nanorods are covered, in an ALD process, with ZnO film at least 1 nm thick, and so created active layer is covered with a transparent ZnO:Al electrode film, which the upper electric contact is made on.

4. The method of claim 3, characterized in that the nucleating layer is deposited on the substrate by cathode sputtering of gold, silver or nanoparticles of those metals.

5. The method of claim 3, characterized in that the nucleating layer is a ZnO layer or ZnO nanoparticles deposited on the substrate from a solution or obtained by annealing zinc salt deposited from a solution or deposited in at least 1 ALD cycle, whereing the zinc precursor is diethylzinc, dimethylzinc or zinc chloride, and the oxygen precursor is water, ozone or oxygen plasma.

6. The method of claim 3, characterized in that the oxygen precursor in the reaction mixture is water, and the zinc precursor is zinc acetate.

7. The method of claim 3, characterized in that the ZnO film that the nanorods of the active layer are covered with is deposited in at least 10 ALD cycles, using diethylzinc, dimethylzinc or zinc chloride as zinc precursor, and water, ozone or oxygen plasma as oxygen precursor.

8. The method of claim 3, characterized in that the transparent ZnO:Al electrode film is deposited in at least 100 ALD cycles with diethylzinc, dimethylzinc or zinc chloride as zinc precursor, water, ozone or oxygen plasma as oxygen precursor, and trimethylaluminum as aluminum precursor.
